(19) United States
(12) Patent Application Publication
(10) Pub. No.: US 2026/0182132 A1
(43) Pub. Date: Jun. 25, 2026

(54) LIGHT-EMITTING DEVICE

(71) Applicant: FOSHAN NATIONSTAR OPTOELECTRONICS CO., LTD., Foshan (CN)

(72) Inventors: Kuai QIN, Foshan (CN); Shaojia XIE, Foshan (CN); Hu XU, Foshan (CN); Feng GU, Foshan (CN); Fangping HE, Foshan (CN); Guilan TIAN, Foshan (CN); Bin CAI, Foshan (CN); Danwei LI, Foshan (CN)

(21) Appl. No.: 19/421,789

(22) Filed: Dec. 16, 2025

(30) Foreign Application Priority Data
Dec. 19, 2024 (CN) 202411891021.7

(51) Int. Cl. H10H 29/80; H10H 20/01; H10H 20/80; H10H 20/84; H10H 20/855; H10H 29/01; H10H 29/24; H10H 29/85; H10H 29/855

(52) U.S. Cl. CPC H10H 29/882; H10H 20/034; H10H 20/0363; H10H 20/84; H10H 20/855; H10H 20/882; H10H 29/034; H10H 29/0363; H10H 29/24; H10H 29/842; H10H 29/8508; H10H 29/855

(57) ABSTRACT

A light-emitting device includes a light-emitting assembly, a first adhesive film, and a second adhesive film. The light-emitting assembly includes a first PCB substrate, a first light-emitting chip, and second light-emitting chips. The first PCB substrate has a mounting surface on one side of the first PCB substrate. The first light-emitting chip and the second light-emitting chips are disposed on the mounting surface. The light emission angle of the first light-emitting chip is less than the light emission angle of each of the second light-emitting chips. The first adhesive film is disposed on the mounting surface. The first adhesive film covers the first light-emitting chip. The second adhesive film covers the second light-emitting chip. The second adhesive film covers and is connected to the light-emitting assembly and the first adhesive film. The refractive index of the first adhesive film is greater than the refractive index of the second adhesive film.

### CROSS-REFERENCE TO RELATED APPLICATION(S)

This application claims priority to Chinese Patent Application No. 202411891021.7 filed Dec. 19, 2024, the disclosure of which is incorporated herein by reference in its entirety.

### TECHNICAL FIELD

The present invention relates to the field of semiconductor manufacturing, particularly a light-emitting device.

### BACKGROUND

At present, with the development of display technology, people have increasingly higher requirements for the display performance of LED display screens. LED display screens are being used in more and more occasions to display, for example, advertising information, product display information, and conference information. Compared with display devices such as calculators, monitors, and household liquid crystal televisions, LED display screens are required to have higher and more uniform brightness and higher reliability. In addition, in application scenarios such as advertising, media, and film and television, LED display screens are required to provide more brilliant image effects, higher color saturation, and better light emission uniformity.

However, in an existing light-emitting device, significant differences occur between the light emission angles of different light-emitting chips mounted on the substrate. This causes a color shift in the emitted light when the light-emitting device is observed at large angles. In other words, the light-emitting device faces the problem of significant color shift at large emission angles, seriously affecting the light emission and display performance of a light-emitting module including the light-emitting device.

### SUMMARY

The present invention provides a light-emitting device. The device enlarges the light emission angles of some of the light-emitting chips by using the scattering effect of a first adhesive film so that the light emission angles of all the light-emitting chips are approximately similar, thereby alleviating the problem of significant color shift at large angles.

The present invention uses the following technical solutions:

A light-emitting device includes a light-emitting assembly, a first adhesive film, and a second adhesive film. The light-emitting assembly includes a first PCB substrate, a first light-emitting chip, and second light-emitting chips. The first PCB substrate has a mounting surface on one side of the first PCB substrate. The first light-emitting chip and the second light-emitting chips are disposed on the mounting surface, and a light emission angle of the first light-emitting chip is less than a light emission angle of each of the second light-emitting chips. The first adhesive film is disposed on the mounting surface. The first adhesive film covers the first light-emitting chip. The first adhesive film is spaced apart from the second light-emitting chips. The second adhesive film covers the second light-emitting chip. The second adhesive film covers and is connected to the light-emitting assembly and the first adhesive film so that the first adhesive film is disposed between the second adhesive film and the light-emitting assembly. The refractive index of the first adhesive film is greater than the refractive index of the second adhesive film.

In an optional solution of the light-emitting device, the first adhesive film includes a first adhesive film layer, the second adhesive film includes a second adhesive film layer, the first PCB substrate, the first adhesive film layer, and the second adhesive film layer are stacked in sequence from bottom to top, through holes penetrate the first adhesive film layer, a number of the through holes is the same as a number of the second light-emitting chips, and each of the second light-emitting chips is disposed in a respective one of the through holes.

In an optional solution of the light-emitting device, protrusions protrude from a surface of the second adhesive film layer, a number of the protrusions is the same as the number of the through holes, and one of the protrusions and one of the second light-emitting chips fill one of the through holes.

In an optional solution of the light-emitting device, the first adhesive film layer is bonded to the second adhesive film layer, and the first adhesive film layer is bonded to the first PCB substrate.

In an optional solution of the light-emitting device, the first adhesive film includes an adhesive film block, the second adhesive film includes a third adhesive film layer, the number of adhesive film blocks is the same as the number of first light-emitting chips, the third adhesive film layer is provided with a blind hole, the blind hole extends along the thickness direction of the first PCB substrate, the number of blind holes is the same as the number of first light-emitting chips, and the adhesive film block and the first light-emitting chip fill the blind hole.

In an optional solution of the light-emitting device, the adhesive film block is recessed to form an accommodation groove, and the first light-emitting chip fills the accommodation groove.

In an optional solution of the light-emitting device, the third adhesive film layer is bonded to the first PCB substrate, and the third adhesive film layer is bonded to the adhesive film block.

In an optional solution of the light-emitting device, a scattering distance is greater than the thickness of the first light-emitting chip. The scattering distance is the distance between the end of the first light-emitting chip facing away from the first PCB substrate and the end of the first adhesive film facing away from the first PCB substrate along the thickness direction of the first PCB substrate.

In an optional solution of the light-emitting device, the material of the first adhesive film includes silicone, epoxy resin, and light-transmitting adhesive; and/or the material of the second adhesive film includes silicone, epoxy resin, and light-transmitting adhesive.

In an optional solution of the light-emitting device, the first adhesive film includes a first scattering powder, and the refractive index of the first adhesive film ranges from 2.0 to 2.5.

In an optional solution of the light-emitting device, the first scattering powder includes zinc oxide, titanium oxide, or zirconium oxide.

In an optional solution of the light-emitting device, the second adhesive film includes a second scattering powder, and the refractive index of the second adhesive film ranges from 1.3 to 1.7.

In an optional solution of the light-emitting device, the second scattering powder includes silica, silicone resin microspheres, and epoxy resin microspheres.

In an optional solution of the light-emitting device, a gap is formed between each second light-emitting chip and the first light-emitting chip, and the gap is filled with at least the first adhesive film.

In an optional solution of the light-emitting device, the light-emitting assembly includes one first light-emitting chip and two second light-emitting chips. The first light-emitting chip is a red light-emitting chip, one of the two second light-emitting chips is a blue light-emitting chip, and the other of the two second light-emitting chips is a green light-emitting chip.

The present invention has the following beneficial effects:

In the light-emitting device, the refractive index of the first adhesive film is different from the refractive index of the second adhesive film, and the first adhesive film covers the first light-emitting chip but does not cover the second light-emitting chips. This effectively enables precise control of the optical path, increases the light emission angle of the first light-emitting chip, prevents the first adhesive film from interfering with light emission of the second light-emitting chips, thereby effectively reduces the difference between the light emission angle of the emitted light of the first light-emitting chip and the light emission angle of the emitted light of the second light-emitting chips in the overall emitted light of the light-emitting device, and thus decreases the color shift of the light-emitting device at large angles.

### BRIEF DESCRIPTION OF DRAWINGS

FIG. 1 is a diagram illustrating the structure of a light-emitting assembly according to embodiment one and embodiment two of the present invention.

FIG. 2 is a diagram illustrating the structure of a first adhesive film layer according to embodiment one of the present invention.

FIG. 3 is a diagram illustrating the structure of a second adhesive film layer according to embodiment one of the present invention.

FIG. 4 is a partial section view of a light-emitting assembly and a first adhesive film layer according to embodiment one of the present invention.

FIG. 5 is a partial top view of a light-emitting assembly and a first adhesive film layer according to embodiment one of the present invention.

FIG. 6 is a partial section view of a light-emitting assembly, a first adhesive film layer, and a second adhesive film layer according to embodiment one of the present invention.

FIG. 7 is a partial top view of a light-emitting assembly, a first adhesive film layer, and a second adhesive film layer according to embodiment one of the present invention.

FIG. 8 is a diagram illustrating the structure of a third adhesive film layer according to embodiment two of the present invention.

FIG. 9 is a partial section view of a light-emitting assembly and an adhesive film block according to embodiment two of the present invention.

FIG. 10 is a partial top view of a light-emitting assembly and an adhesive film block according to embodiment two of the present invention.

FIG. 11 is a partial section view of a light-emitting assembly, an adhesive film block, and a third adhesive film layer according to embodiment two of the present invention.

FIG. 12 is a partial top view of a light-emitting assembly, an adhesive film block, and a third adhesive film layer according to embodiment two of the present invention.

### REFERENCE LIST

110. first PCB substrate; 120. second light-emitting chip; 140. first light-emitting chip;
200. first adhesive film layer; 201. through hole;
300. second adhesive film layer; 301. protrusion;
400. adhesive film block;
500. third adhesive film layer; 501. blind hole

### DETAILED DESCRIPTION

The technical solutions of the present invention are described clearly and completely below in conjunction with the drawings. Apparently, the described embodiments are part, not all, of the embodiments of the present invention. Based on the embodiments of the present invention, all other embodiments obtained by those of ordinary skill in the art without creative work are within the scope of the present invention.

In the description of the present invention, it is to be noted that orientations or position relations indicated by terms such as “center”, “upper”, “lower”, “left”, “right”, “vertical”, “horizontal”, “in”, and “out” are based on the drawings. These orientations or position relations are intended only to facilitate and simplify the description of the present invention and not to indicate or imply that a device or element referred to must have such particular orientations or must be configured or operated in such particular orientations. Thus, these orientations or position relations are not to be construed as limiting the present invention. In addition, terms such as “first” and “second” are used only for the purpose of description and are not to be construed as indicating or implying relative importance. The terms “first position” and “second position” are two different positions. Moreover, when a first feature is described as “on”, “above”, or “over” a second feature, the first feature is right on, above, or over the second feature, the first feature is obliquely on, above, or over the second feature, or the first feature is simply at a higher level than the second feature. When the first feature is described as “under”, “below”, or “underneath” the second feature, the first feature is right under, below, or underneath the second feature, the first feature is obliquely under, below, or underneath the second feature, or the first feature is simply at a lower level than the second feature.

In the description of the present invention, it is to be noted that unless otherwise expressly specified and limited, the term “mounted”, “connected to each other”, or “connected” should be construed in a broad sense, for example, as securely connected, detachably connected, or integrally connected; mechanically connected or electrically connected; directly connected to each other or indirectly connected to each other via an intermediary; or interconnected between two elements. For those of ordinary skill in the art, specific meanings of the preceding terms in the present invention may be understood based on specific situations.

Embodiments of the present invention are described in detail below. Examples of the embodiments are illustrated in the drawings, where the same or similar reference numerals throughout the drawings represent the same or similar elements or elements having the same or similar functions. The embodiments described below with reference to the drawings are illustrative and intended only to explain the present invention and cannot be construed as limiting the present invention.

### Embodiment One

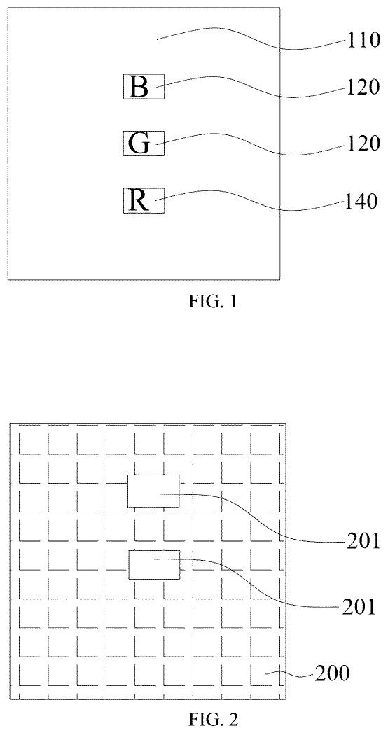

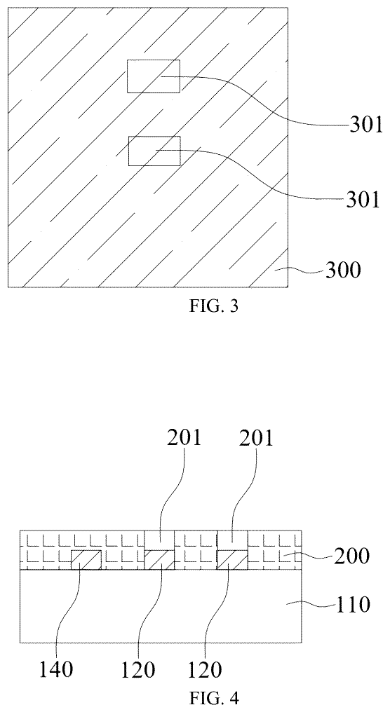

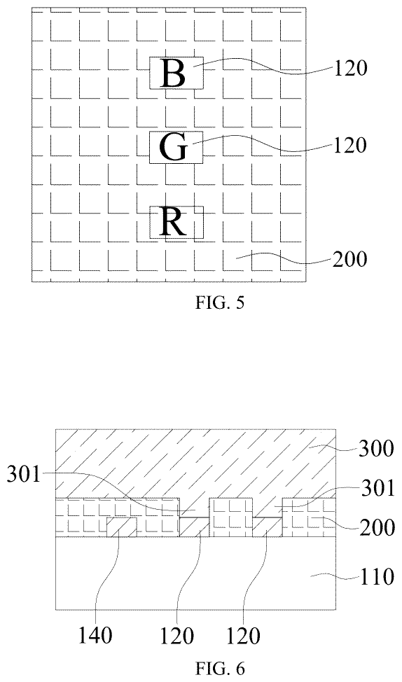

As shown in FIG. 1 to FIG. 7, an embodiment provides a light-emitting device. The light-emitting device includes a light-emitting assembly, a first adhesive film, and a second adhesive film. The light-emitting assembly includes a first PCB substrate 110, a first light-emitting chip 140, and second light-emitting chips 120. The first PCB substrate 110 has a mounting surface on one side of the first PCB substrate. The first light-emitting chip 140 and the second light-emitting chips 120 are disposed on the mounting surface. The light emission angle of the first light-emitting chip 140 is less than the light emission angle of each of the second light-emitting chips 120. The first adhesive film is disposed on the mounting surface. The first adhesive film covers the first light-emitting chip 140. The first adhesive film is spaced apart from the second light-emitting chips 120. The second adhesive film covers the second light-emitting chips 120. The second adhesive film covers and is connected to the light-emitting assembly and the first adhesive film so that the first adhesive film is disposed between the second adhesive film and the light-emitting assembly. The refractive index of the first adhesive film is greater than the refractive index of the second adhesive film.

In the light-emitting device, the refractive index of the first adhesive film is different from the refractive index of the second adhesive film, and the first adhesive film covers the first light-emitting chip 140 but does not cover the second light-emitting chips 120. This effectively enables precise control of the optical path, increases the light emission angle of the first light-emitting chip 140, prevents the first adhesive film from interfering with light emission of the second light-emitting chips 120, thereby effectively reduces the difference between the light emission angle of the emitted light of the first light-emitting chip 140 and the light emission angle of the emitted light of the second light-emitting chips 120 in the overall emitted light of the device, and thus decreases the color shift of the light-emitting device at large angles.

The first adhesive film and the second adhesive film differ in refractive index, enabling effective regulation and scattering of light and improving the light emission efficiency and the light uniformity of the light-emitting device. The second adhesive film covers and is connected to the light-emitting assembly and the first adhesive film, and the first adhesive film is disposed between the second adhesive film and the light-emitting assembly. This dual adhesive film structure enhances the sealing and durability of the light-emitting device. With the multi-film structure, the light emission angle of the first light-emitting chip 140 and the light emission angle of the second light-emitting chips 120 are similar, enabling efficient and stable light control and transmission. Thus, the light-emitting device has broad application prospects and economic benefits.

By way of example, a scattering distance is greater than the thickness of the first light-emitting chip 140. The scattering distance is the distance between the end of the first light-emitting chip 140 facing away from the first PCB substrate 110 and the end of the first adhesive film facing away from the first PCB substrate 110 along the thickness direction of the first PCB substrate 110.

The design of making the scattering distance greater than the thickness of the first light-emitting chip 140 optimizes the scattering of light, enables effective control of light propagation, improves the light emission uniformity and brightness of the light-emitting device, and contributes to more uniform light emission.

In an implementation of this embodiment, the material of the first adhesive film includes silicone, epoxy resin, and light-transmitting adhesive; and the material of the second adhesive film includes silicone, epoxy resin, and light-transmitting adhesive.

Multiple material options are available for the first adhesive film and the second adhesive film, including silicone, epoxy resin, and light-transmitting adhesive. These materials possess excellent optical properties and thermal stability, meeting various application requirements and endowing the light-emitting device with broader applicability and superior durability.

In another implementation of this embodiment, the material of only the first adhesive film includes silicone, epoxy resin, and light-transmitting adhesive. In another implementation of this embodiment, the material of only the second adhesive film includes silicone, epoxy resin, and light-transmitting adhesive.

Specifically, both the first adhesive film and the second adhesive film may be made of bisphenol-A epoxy, organosilicone resin, or inorganic silicone resin. The first adhesive film and the second adhesive film made of bisphenol-A epoxy, organosilicone resin, or inorganic silicone resin can improve the performance stability and the service life of the light-emitting device and optimize the light transmission effect. Bisphenol-A epoxy, organosilicone resin, and inorganic silicone resin are conventional materials in the art. The beneficial effects of their application are well known to those skilled in the art and thus are not described in detail here.

In this embodiment, the first adhesive film includes a first scattering powder, and the refractive index of the first adhesive film ranges from 2.0 to 2.5.

The design of adding the first scattering powder to the first adhesive film can enhance the light scattering effect and achieve light guidance, thereby regulating the propagation and scattering of light and improving the overall performance of the light-emitting device. Moreover, the design of controlling the refractive index of the first adhesive film within a range enables effective light scattering and regulation, improves the uniformity of light distribution and visual effect of the light-emitting device, and helps achieve optimal light performance.

Moreover, the first scattering powder includes zinc oxide, titanium oxide, or zirconium oxide.

The first scattering powder is selected from zinc oxide, titanium oxide, or zirconium oxide, providing multiple material options and optimizing the light scattering effect.

In this embodiment, the second adhesive film includes a second scattering powder, and the refractive index of the second adhesive film ranges from 1.3 to 1.7.

The design of adding the second scattering powder to the second adhesive film can enhance the light scattering effect and achieve light guidance, thereby regulating the propagation and scattering of light and improving the overall performance of the light-emitting device. Moreover, the design of controlling the refractive index of the second adhesive film within a range enables effective light scattering and regulation, improves the uniformity of light distribution and visual effect of the light-emitting device, and helps achieve optimal light performance in cooperation with the first adhesive film.

Further, the second scattering powder includes silica, silicone resin microspheres, and epoxy resin microspheres.

The second scattering powder is selected from silica, silicone resin microspheres, and epoxy resin microspheres, providing diversified modes for light control and optimizing the light scattering effect.

The first scattering powder and the second scattering powder both serve to modify the scattering properties, thereby increasing the light emission angle. However, an incorrect proportion of the scattering powder may lead to light absorption and refractive index mismatch, causing a loss of emitted light energy of the light-emitting device and affecting the light emission performance and the light performance of the light-emitting device. In addition, the scattering powder is relatively expensive and not widely used, so strict requirements are imposed on the proportion and mixing uniformity of the scattering powder.

In this embodiment, a gap is formed between each second light-emitting chip 120 and the first light-emitting chip 140, and the gap is filled with at least the first adhesive film.

The gap between the second light-emitting chips 120 and the first light-emitting chip 140 is filled with the first adhesive film, ensuring the compactness and uniformity of the light-emitting assembly, maintaining the structural stability and uniform light distribution of the light-emitting device, and enhancing the overall durability and reliability.

By way of example, the light-emitting assembly includes one first light-emitting chip 140 and two second light-emitting chips 120, the first light-emitting chip 140 is a red light-emitting chip, one of the two second light-emitting chips 120 is a blue light-emitting chip, and the other of the two second light-emitting chips 120 is a green light-emitting chip.

Red, blue, and green light-emitting chips are used in combination, enabling various color mixing and adjustment, enabling the emission of colored light, enhancing the color performance and the visual effect of the light-emitting device, and meeting the application requirements of the display screen.

In this embodiment, the first adhesive film includes a first adhesive film layer 200, the second adhesive film includes a second adhesive film layer 300, the first PCB substrate 110, the first adhesive film layer 200, and the second adhesive film layer 300 are stacked in sequence from bottom to top, through holes 201 penetrate the first adhesive film layer 200, a number of the through holes 201 is the same as a number of the second light-emitting chips 120, and each second light-emitting chip 120 is disposed in a respective one of the through holes.

The stacked structure of the first adhesive film layer 200 and the second adhesive film layer 300, together with the through holes 201, ensures a precise match between the first adhesive film layer 200 and the second light-emitting chips 120, allows the second light-emitting chips 120 to be effectively fixed, enables both secure fixation and light control of the second light-emitting chip 120, ensures that the first adhesive film covers the first light-emitting chip 140 without covering the second light-emitting chip 120, enables precise control of light propagation and scattering, and improves the structural stability and uniform light distribution of the light-emitting device. Moreover, the first adhesive film layer 200 that covers the entire first PCB substrate 110 has a simple structure and is easy to manufacture, improving the manufacturing efficiency of the light-emitting device.

Further, protrusions 301 protrude from a surface of the second adhesive film layer 300, the number of the protrusions 301 is the same as the number of the through holes 201, and one of the protrusions 301 and one of the second light-emitting chips 120 fill one of the through holes 201.

The protrusions 301 on the surface of the second adhesive film layer 300 corresponds to the through holes 201, allowing the second light-emitting chips 120 to fill the through holes 201 more stably, ensures good adhesion between the second adhesive film layer 300 and the first adhesive film layer 200, prevents displacement or detachment of the second light-emitting chips 120, enables control of the propagation direction of light, and enhances the structural stability and the light scattering effect of the light-emitting device.

Further, the first adhesive film layer 200 is bonded to the second adhesive film layer 300, and the first adhesive film layer 200 is bonded to the first PCB substrate 110.

The strong bonding between the first adhesive film layer 200 and the second adhesive film layer 300 and between the first adhesive film layer 200 and the first PCB substrate 110 ensures the firmness of the light-emitting assembly, enables a stable connection between the components of the light-emitting device, enhances the overall structural stability and durability, improves the yield and reliability of the device, and ensures the accuracy of light propagation.

This embodiment also provides a light-emitting module. The light-emitting module includes a second PCB substrate and at least one preceding light-emitting device. The light-emitting device is disposed on the second PCB substrate. The side of the first PCB substrate 110 facing away from the mounting surface is connected to the second PCB substrate.

The design of disposing the light-emitting device of the light-emitting module on the second PCB substrate enables a stable connection between the light-emitting device and the substrate and enhances the structural integrity and stability of the light-emitting module. The side of the first PCB substrate 110 facing away from the mounting surface is connected to the second PCB substrate, enabling convenient mounting and modular design of the light-emitting device, making the light-emitting module easier to assemble and apply, and improving both the manufacturing efficiency and the mounting efficiency.

This embodiment also provides a manufacturing method of a light-emitting device. The manufacturing method is configured to manufacture the preceding light-emitting device. The method includes:
S1: providing a main board, first light-emitting chips 140, and second light-emitting chips 120, where the main board includes multiple first PCB substrates 110 disposed in an array and connected to each other and mounting surfaces of the multiple first PCB substrates 110 face the same side of the main board, and disposing the first light-emitting chips 140 and the second light-emitting chips 120 on the mounting surfaces of the multiple first PCB substrates 110;
S2: forming a first film on the mounting surfaces of the multiple first PCB substrates and the first light-emitting chips 140;
S3: forming a second film on the first film and the second light-emitting chips 120; and
S4: cutting the main board and the first film, and the second film to separate the multiple first PCB substrates 110 from each other to obtain the light-emitting device, where the first film is cut into first adhesive films, and the second film is cut into second adhesive films.

The manufacturing method of the light-emitting device provides a main board including multiple first PCB substrates 110 disposed in an array and connected to each other, thereby enabling batch manufacturing of multiple light-emitting devices and improving the manufacturing efficiency. Precise steps are used to form the first adhesive film and the second adhesive film, ensuring stable bonding between the adhesive film and the light-emitting assembly and enhancing the reliability of the manufacturing process and the stability of the product quality. The main board and the adhesive film are cut to obtain the individual light-emitting device, thereby simplifying the manufacturing process and improving the manufacturing efficiency.

In this embodiment, the first adhesive film includes a thermosetting resin, and S2 includes molding and bonding the first adhesive film onto the first light-emitting chips 140 by thermoplastic curing; and the second adhesive film includes a thermosetting resin, and S3 includes molding and bonding the second film onto the first film and the light-emitting assembly by thermoplastic curing.

The thermosetting resin is used as the material of the adhesive film, and the adhesive film is firmly molded and bonded to the light-emitting assembly by thermoplastic curing, thereby enhancing the adhesion and durability of the adhesive film, simplifying the manufacturing process, improving the manufacturing efficiency, and extending the service life. The precise curing steps ensure uniformity and consistency of the thermosetting resin during the curing process and enhance the quality and reliability of the product. Moreover, the overall thermosetting process is easy to control, making it suitable for large-scale production.

Specifically, the main material of the first adhesive film and the main material of the second adhesive film both include a thermosetting resin. The thermosetting resin possesses high adhesion strength and can maintain good performance even under high-temperature conditions. The added curing agent works in combination to enhance the adhesive properties, promoting the crosslinking reaction of the epoxy resin to form an insoluble thermosetting polymer. The resulting chemical bonding and physical entanglement create a strong adhesion between the first adhesive film and the second adhesive film, thereby enabling direct molding and bonding by thermoplastic curing.

### Embodiment Two

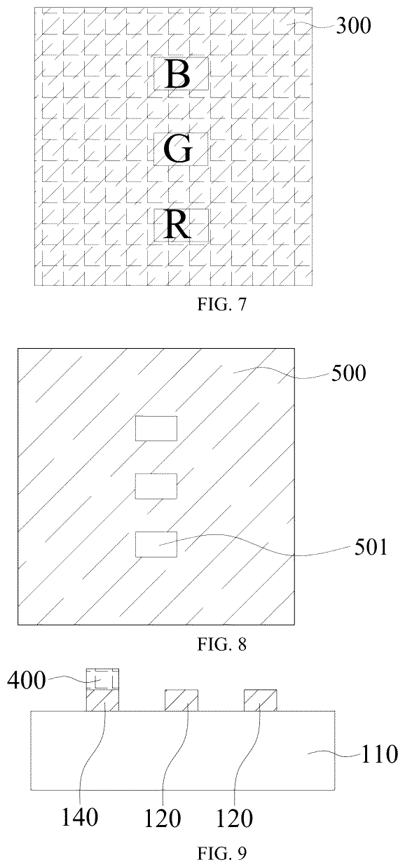

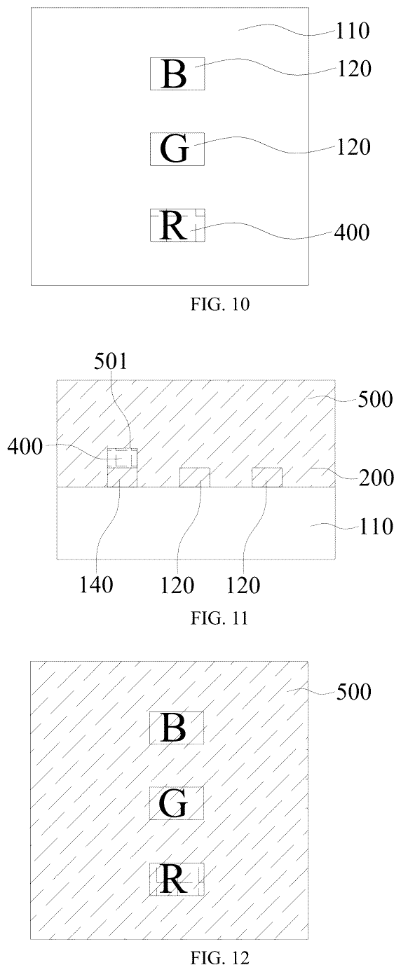

As shown in FIG. 1 and FIG. 8 to FIG. 12, the light-emitting device of embodiment two is substantially the same as that of embodiment one. The difference lies in that the first adhesive film includes an adhesive film block 400, the second adhesive film includes a third adhesive film layer 500, the number of adhesive film blocks 400 is the same as the number of first light-emitting chips 140, the third adhesive film layer 500 is provided with a blind hole 501, the blind hole 501 extends along the thickness direction of the first PCB substrate 110, the number of blind holes 501 is the same as the number of first light-emitting chips 140, and the adhesive film block 400 and the first light-emitting chip 140 fill the blind hole 501.

The design of providing the same number of adhesive film blocks 400 as the first light-emitting chips 140 and forming the blind hole 501 in the third adhesive film layer 500 enables precise positioning and light guiding for the first light-emitting chip 140, optimizes the light propagation path, enhances the light utilization efficiency of the first light-emitting chip 140, and improves the overall uniformity of light emission. The arrangement of multiple adhesive film blocks 400 can reduce the demand for the first adhesive film, thereby lowering the production cost of the light-emitting device.

Further, the adhesive film block 400 is recessed to form an accommodation groove, and the first light-emitting chip 140 fills the accommodation groove.

The design of the recessed accommodation groove in the adhesive film block 400 ensures that the first light-emitting chip 140 is fully embedded within the groove, thereby securing the structural stability of the first light-emitting chip 140 and enabling effective light transmission and scattering. This enhances the light guiding performance of the light-emitting device and improves the overall light emission effect.

In this embodiment, the third adhesive film layer 500 is bonded to the first PCB substrate 110 and is also bonded to the adhesive film block 400.

The bonding of the third adhesive film layer 500 to the first PCB substrate 110 and to the adhesive film block 400 ensures the stability and uniformity of the light-emitting device and enables the overall light control.

This embodiment also provides a light-emitting module. The light-emitting module includes a second PCB substrate and at least one preceding light-emitting device. The light-emitting device is disposed on the second PCB substrate. The side of the first PCB substrate 110 facing away from the mounting surface is connected to the second PCB substrate.

The design of disposing the light-emitting device of the light-emitting module on the second PCB substrate enables a stable connection between the light-emitting device and the substrate and enhances the structural integrity and stability of the light-emitting module. The side of the first PCB substrate 110 facing away from the mounting surface is connected to the second PCB substrate, enabling convenient mounting and modular design of the light-emitting device, making the light-emitting module easier to assemble and apply, and improving both the manufacturing efficiency and the mounting efficiency.

This embodiment also provides a manufacturing method of a light-emitting device. The manufacturing method is configured to manufacture the preceding light-emitting device. The method includes:
S1: providing a main board, the first light-emitting chip 140, and the second light-emitting chips 120, where the main board includes multiple first PCB substrates 110 disposed in an array and connected to each other and surfaces of the multiple first PCB substrates 110 face the same side of the main board, and disposing the first light-emitting chip 140 and the second light-emitting chip 120 on the mounting surface of each first PCB substrate 110;
S2: forming the first film on the mounting surfaces and the first light-emitting chips 140;
S3: forming the second film on the first film and the second light-emitting chip 120; and
S4: cutting the main board and the first film, and the second film to separate the multiple first PCB substrates 110 from each other to obtain the light-emitting device, where the first film is cut into first adhesive films, and the second film is cut into second adhesive films.

The manufacturing method of the light-emitting device provides a main board including multiple first PCB substrates 110 disposed in an array and connected to each other, thereby enabling batch manufacturing of multiple light-emitting devices and improving the manufacturing efficiency. Precise steps S2 and S3 are used to form the first adhesive film and the second adhesive film, ensuring stable bonding between the adhesive films and the light-emitting assembly and enhancing the reliability of the manufacturing process and the stability of the product quality. The main board and the adhesive films are cut to obtain the individual light-emitting device, thereby simplifying the manufacturing process and improving the manufacturing efficiency.

In this embodiment, the first adhesive film includes a thermosetting resin, and S2 includes molding and bonding the first film onto the first light-emitting chips by thermoplastic curing; and the second adhesive film includes a thermosetting resin, and S3 includes molding and bonding the second film onto the first film and the light-emitting assembly by thermoplastic curing.

The thermosetting resin is used as the material of the adhesive films, and the adhesive films are firmly molded and bonded to the light-emitting assembly by thermoplastic curing, thereby enhancing the adhesion and durability of the adhesive films, simplifying the manufacturing process, improving the manufacturing efficiency, and extending the service life. The precise curing steps ensure uniformity and consistency of the thermosetting resin during the curing process and enhance the quality and reliability of the product. Moreover, the overall thermosetting process is easy to control, making it suitable for large-scale production.

Specifically, the main material of the first adhesive film and the main material of the second adhesive film both include a thermosetting resin. The thermosetting resin possesses high adhesion strength and can maintain good performance even under high-temperature conditions. The added curing agent works in combination to enhance the adhesive properties, promoting the crosslinking reaction of the epoxy resin to form an insoluble thermosetting polymer. The resulting chemical bonding and physical entanglement create a strong adhesion between the first adhesive film and the second adhesive film, thereby enabling direct molding and bonding by thermoplastic curing.

Apparently, the preceding embodiments of the present invention are illustrative examples of the present invention and are not intended to limit the implementations of the present invention. Those of ordinary skill in the art can make changes or variations in other different forms based on the preceding description. All embodiments do not need to be and cannot be exhausted herein. Any modifications, equivalent substitutions, and improvements made within the spirit and principle of the present invention fall within the scope of the claims of the present invention.

What is claimed is:

1. A light-emitting device, comprising:
a light-emitting assembly comprising a first PCB substrate, a first light-emitting chip, and second light-emitting chips, wherein the first PCB substrate has a mounting surface on one side of the first PCB substrate, the first light-emitting chip and the second light-emitting chips are disposed on the mounting surface, and a light emission angle of the first light-emitting chip is less than a light emission angle of each of the second light-emitting chips;
a first adhesive film disposed on the mounting surface, wherein the first adhesive film covers the first light-emitting chip, and the first adhesive film is spaced apart from the second light-emitting chips; and
a second adhesive film covering the second light-emitting chips, wherein the second adhesive film covers and is connected to the light-emitting assembly and the first adhesive film so that the first adhesive film is disposed between the second adhesive film and the light-emitting assembly, and a refractive index of the first adhesive film is greater than a refractive index of the second adhesive film.

2. The light-emitting device of claim 1, wherein the first adhesive film comprises a first adhesive film layer, the second adhesive film comprises a second adhesive film layer, the first PCB substrate, the first adhesive film layer, and the second adhesive film layer are stacked in sequence from bottom to top, through holes penetrate the first adhesive film layer, a number of the through holes is same as a number of the second light-emitting chips, and each of the second light-emitting chips is disposed in a respective one of the through holes.

3. The light-emitting device of claim 2, wherein protrusions protrude from a surface of the second adhesive film layer, a number of the protrusions is same as the number of the through holes, and one of the protrusions and one of the second light-emitting chips fill one of the through holes.

4. The light-emitting device of claim 3, wherein the first adhesive film layer is bonded to the second adhesive film layer, and the first adhesive film layer is bonded to the first PCB substrate.

5. The light-emitting device of claim 1, wherein the first adhesive film comprises an adhesive film block, the second adhesive film comprises a third adhesive film layer, the third adhesive film layer is provided with a blind hole, the blind hole extends along a thickness direction of the first PCB substrate, and the adhesive film block and the first light-emitting chip fill the blind hole.

6. The light-emitting device of claim 5, wherein the adhesive film block is recessed to form an accommodation groove, and the first light-emitting chip fills the accommodation groove.

7. The light-emitting device of claim 5, wherein the third adhesive film layer is bonded to the first PCB substrate, and the third adhesive film layer is bonded to the adhesive film block.

8. The light-emitting device of claim 1, wherein a scattering distance is greater than a thickness of the first light-emitting chip, wherein the scattering distance is a distance between an end of the first light-emitting chip facing away from the first PCB substrate and an end of the first adhesive film facing away from the first PCB substrate along a thickness direction of the first PCB substrate.

9. The light-emitting device of claim 1, wherein
a material of the first adhesive film comprises silicone, epoxy resin, and light-transmitting adhesive; and/or
a material of the second adhesive film comprises silicone, epoxy resin, and light-transmitting adhesive.

10. The light-emitting device of claim 1, wherein the first adhesive film comprises a first scattering powder, and the refractive index of the first adhesive film ranges from 2.0 to 2.5.

11. The light-emitting device of claim 10, wherein the first scattering powder comprises zinc oxide, titanium oxide, or zirconium oxide.

12. The light-emitting device of claim 1, wherein the second adhesive film comprises a second scattering powder, and the refractive index of the second adhesive film ranges from 1.3 to 1.7.

13. The light-emitting device of claim 12, wherein the second scattering powder comprises silica, silicone resin microspheres, and epoxy resin microspheres.

14. The light-emitting device of claim 1, wherein a gap is formed between each of the second light-emitting chips and the first light-emitting chip, and the gap is filled with at least the first adhesive film.

15. The light-emitting device of claim 1, wherein the light-emitting assembly comprises one first light-emitting chip and two second light-emitting chips, the one first light-emitting chip is a red light-emitting chip, one of the two second light-emitting chips is a blue light-emitting chip, and another of the two second light-emitting chips is a green light-emitting chip.

16. The light-emitting device of claim 2, wherein the light-emitting assembly comprises one first light-emitting chip and two second light-emitting chips, the one first light-emitting chip is a red light-emitting chip, one of the two second light-emitting chips is a blue light-emitting chip, and another of the two second light-emitting chips is a green light-emitting chip.

17. The light-emitting device of claim 1, wherein the light-emitting assembly comprises a plurality of first light-emitting chips;
the first adhesive film comprises adhesive film blocks, the second adhesive film comprises a third adhesive film layer, a number of the adhesive film blocks is same as a number of the plurality of first light-emitting chips, the third adhesive film layer is provided with blind holes, each of the blind holes extend along a thickness direction of the first PCB substrate, a number of the blind holes is same as the number of the plurality of first light-emitting chips, and one of the adhesive film blocks and one of the plurality of first light-emitting chips fill one of the blind holes.
